(19) United States
(12) Patent Application Publication
(10) Pub. No.: US 2010/0170566 A1
(43) Pub. Date: Jul. 8, 2010

(54) APPARATUS AND METHOD FOR MANUFACTURING POLYMER SOLAR CELLS

(76) Inventor: Arthur Don Harmala, Saline, MI (US)

Correspondence Address: JELIC PATENT SERVICES, LLC, 2922 MARSHALL ST, ANN ARBOR, MI, 48108, US

(21) Appl. No.: 12/647,080

(22) Filed: Dec. 24, 2009

Related U.S. Application Data
(60) Provisional application No. 61/142,724, filed on Jan. 6, 2009.

(51) Int. Cl. H01L 31/02; B29C 45/00

(52) U.S. Cl. 136/256; 425/90; 264/129; 264/1.32

(57) ABSTRACT

The present disclosure provides an apparatus and method for manufacturing polymer solar cells. The apparatus is designed to adapt many techniques used in the compact disc manufacturing industry to the manufacture of polymer solar cells. The apparatus comprises: means for creating a polymer substrate for a solar cell with a polycarbonate injection molding machine; means for depositing a cathodic contact layer on the polymer substrate; means for depositing a photonic energy absorbing layer on the polymer substrate with directed energy; means to use a thermal process chamber for formation of a CIGS absorber layer; means for depositing a buffer layer on the polymer substrate; means for depositing a highly resistive transmissive intrinsic layer with directed energy; means for depositing a transmissive contact layer on the polymer substrate; means for adding anodic contacts to one of the layers; means for depositing an anti-reflective coating layer on the polymer substrate; and means for encapsulating the solar cell to provide environmental protection.

### CROSS-REFERENCE TO RELATED APPLICATIONS

This application claims the benefit of U.S. Provisional Application 61/142,724 filed Jan. 6, 2009. The content of this prior application is incorporated by reference in its entirety.

### BACKGROUND OF THE INVENTION

Solar cell manufacturing methods typically use either glass substrates, metal foil, or plastic film substrates. The foil or film substrates, also known as thin film solar, are made on roll-to-roll (R2R) systems. These R2R systems are conceptually similar to newspaper printing systems.

### BRIEF SUMMARY OF THE INVENTION

The present disclosure provides an apparatus and method for manufacturing polymer solar cells. The apparatus is designed to adapt many techniques used in the compact disc manufacturing industry to the manufacture of polymer solar cells. The apparatus comprises: means for creating a polymer substrate for a solar cell with a polycarbonate injection molding machine; means for depositing a cathodic contact layer on the polymer substrate; means for depositing a photonic energy absorbing layer on the polymer substrate with directed energy; means to use a thermal process chamber for formation of a CIGS absorber layer; means for depositing a buffer layer on the polymer substrate; means for depositing a highly resistive transmissive intrinsic layer with directed energy; means for depositing a transmissive contact layer on the polymer substrate; means for adding anodic contacts to one of the layers; means for depositing an anti-reflective coating layer on the polymer substrate; and means for encapsulating the solar cell to provide environmental protection.

The apparatus and method also enable the use of polymer additives to change the characteristics of the polymer substrate. For example, borosilicate glass spheres may be incorporated in the polymer to lower the overall density of the solar cell. The lower density enables applications where the weight of the solar cell is critical.

The apparatus and method are capable of manufacturing polymer solar cells in any shape required. Examples of shapes include but are not limited to: circular, square, rectangular, trapezoidal, triangular, and oval.

A primary benefit of the invention is the ability to make molded substrates which employ a Fresnel lens, or the like, feature on the topside and a textured surface on the absorber layer side. The Fresnel lens, or the like, feature allows light to be focused or concentrated, for many equivalent suns energy, onto the copper indium gallium (di) selenide (CIGS) absorber layer. The polymer substrate underside is textured to give the solar cell additional surface area, verses a flat surface, for higher photon absorption capability.

Another primary benefit of the invention is the ability to make molded substrates which can employ a Fresnel lens, or the like, feature on the photon entrance side of the superstrate solar cell with an inverted configuration. A textured surface can also be molded on the surface of the cell nearest to the CIGS absorber layer, opposite the lens side for a superstrate solar cell, for more surface area to enhance photon absorption. A cell where photonic energy does not pass through the substrate would only have the ability for a textured surface on the topside of the polymer substrate.

### BRIEF DESCRIPTION OF THE DRAWINGS

FIG. 1 shows a cross-section view of one possible embodiment of a polymer solar cell.

FIG. 2 shows a cross-section view of a second possible embodiment of a polymer solar cell.

FIG. 3 shows a cross-section view of a third possible embodiment of a polymer solar cell.

FIG. 4 shows a sequence of steps used to create a polymer solar cell.

FIG. 5 shows an embodiment of the apparatus used to create a polymer solar cell.

### DETAILED DESCRIPTION OF THE INVENTION

The present disclosure describes an apparatus and method for manufacturing polymer solar cells. The apparatus and method utilize concepts developed in the compact and digital versatile disc (CD/DVD) manufacturing industry. Advantages of the apparatus and method over glass substrate manufacturing include a less expensive material handling system, small area vacuum process, more durable product, and a lighter-weight product. Advantages of the apparatus and method over glass, foil, or film substrates include smaller manufacturing space requirements, lower fixed costs, and better quality control. The quality control is better because the apparatus and method use a discrete manufacturing method while glass, foil, or film substrates use a continuous, larger-surface-area manufacturing method.

Previous attempts to manufacture polymer solar cells have failed due to the high temperature required for proper formation of the Cu(In,Ga)(Se,S)₂ (CIGS) absorber layer on the polymer substrate. Deposition and formation of the CIGS layer typically required temperatures of 400-550 degrees Celsius. Methods of deposition of the absorber layer at an elevated temperature by substrate heating or in-situ environment precluded use of polymer substrates or required the process to be done at lower temperatures. However, typical polymer materials such as polycarbonate or polyimide melt at about 305 degrees Celsius and 400 degrees Celsius respectively. Hence, there is prior art which teaches away from using a polymer as a substrate in solar cells.

Examples of prior art which teach away from using a polymer as a substrate are:
A. Polyimide films—Polyimide substrate temperature is limited to 400° C. to 450° C. Birkmire et al. 3-2005, “Cu(InGa)Se2 Solar Cells on a Flexible Polymer Web”, Institute of Energy Conversion, University of Delaware, Newark, Del. 19716, p 190, 193. Inventor's Note: “Dr. Birkmire is a listed co-author of this paper, he advised me on the phone that using a polycarbonate substrate will never work, and he therefore declined to assist me in making prototypes as it would be a waste of time.”, call on Apr. 13, 2009.
B. Eser et al. 9-2005, “Critical Issues for Cu(InGa)Se2 Solar Cells on Flexible Polymer Web”, Institute of Energy Conversion, University of Delaware, Newark, Del. 19716
Abstract comment, line 10-11: “In addition, polymer substrates, cannot be used at temperatures that are optimum for Cu(InGa)Se₂ deposition.”
C. Hoffman et al. July 2000, “Thin-Film Photovoltaic Solar Array Parametric Assessment”, NASA/TM-2000-210342, Glenn Research Center, Cleveland, Ohio, AIAA-2000-2919, page 6 (2) Polyimides, or other polymer substrate materials. Hoffman, page 6(2) “ . . . cells with moderate efficiency on lightweight substrates can compete on a mass basis, higher cell efficiencies will be required to mitigate impacts associated with large array area. Current thin-film cell fabrication approaches are limited by either (1) the ultimate efficiency that can be achieved with the device material and structure, or (2) the requirement for high temperature deposition processes that are incompatible with all presently known flexible polyimides, or other polymer substrate materials.”

The present apparatus and method utilize highly directed energy, such as sputtering, for deposition of the CIGS precursor metals layer on the substrate at a low temperature to not affect the polymer substrate and to be followed by rapid thermal processing, possibly at specific wavelengths, to overcome the limitations of the prior art. The rapid thermal processing consists of highly controlled and directed energy for formation, by selenization or sulfurization of the absorber layer alloy, of the CIGS metal precursors layer while minimizing the melting of the polymer substrate.

The apparatus and method also enable the use of polymer additives to change the characteristics of the polymer substrate. For example, borosilicate glass spheres may be incorporated into the polymer to lower the overall density of the solar cell. The lower density enables applications where the weight of the solar cell is critical.

The apparatus and method are capable of manufacturing polymer solar cells in any shape required. Examples of shapes include but are not limited to; circular, square, rectangular, trapezoidal, triangular, and oval.

The polymer solar cell will have a topside and an underside. Photonic energy from the sun enters through the topside.

One unexpected result of the apparatus and method is that the product yield can be significantly increased by the discrete process versus an overall scrap rate caused by high speed continuous inline inability to immediately correct substandard production. So, defective product may be isolated and fixed prior to additional steps in the manufacturing process. Also, different portions of the apparatus may be removed from service without affecting other portions of the apparatus.

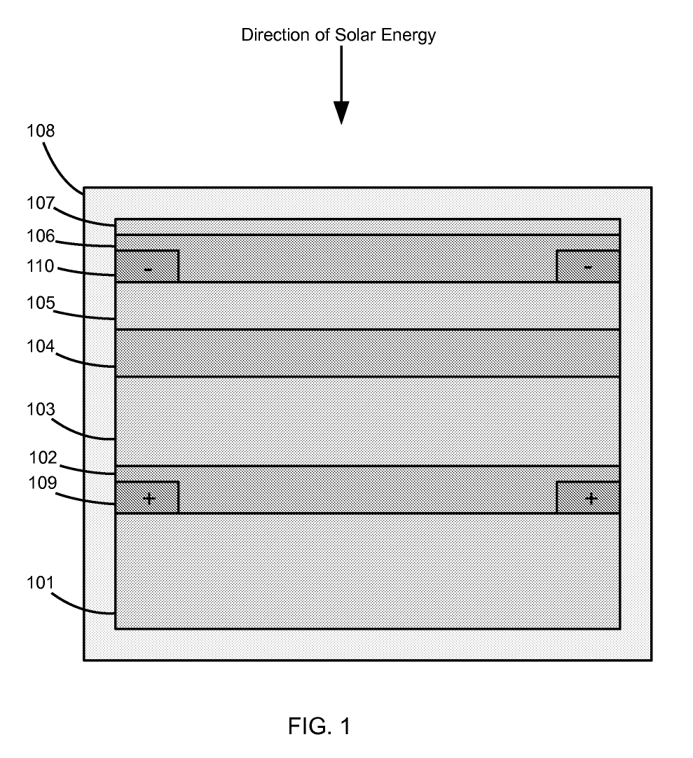

A cross-section view of one possible embodiment of a polymer solar cell is shown in FIG. 1. The first step is to create a polymer substrate 101 using a polycarbonate injection molding machine. The following layers, steps two through seven, are added on the topside of the polymer solar cell. The second step is to add a Molybdenum back contact layer 102 with a thickness of 0.9-2 microns. Cathodic (+) contact pads 109 may be deposited on the back contact layer 102. Third, a CuInGaSe₂ (CIGS) layer 103 is added with a thickness of 1.8-2.2 microns. The CIGS layer 103 absorbs photonic energy. Fourth, a Cadmium Sulfide (CdS) buffer layer 104 is added with a thickness of 40-60 nanometers. The CdS layer 104 functions as a heterojunction partner buffer. Fifth, an intrinsic-Zinc Oxide (i-ZnO) n-type highly resistive window layer 105 is added with a thickness about 30-50 nm. Sixth, an aluminum doped Zinc Oxide (ZnO:Al) transmissive contact layer 106 is added with a thickness of 0.3-0.5 microns. Anodic (−) bi-layer contacts 110 made of aluminum and nickel are deposited on the transmissive contact layer 106. Seventh, an anti-reflective (AR) coating 107 is added. Finally, the entire solar cell is encapsulated 108 using a technique designed to provide environmental protection and give twenty years of service life.

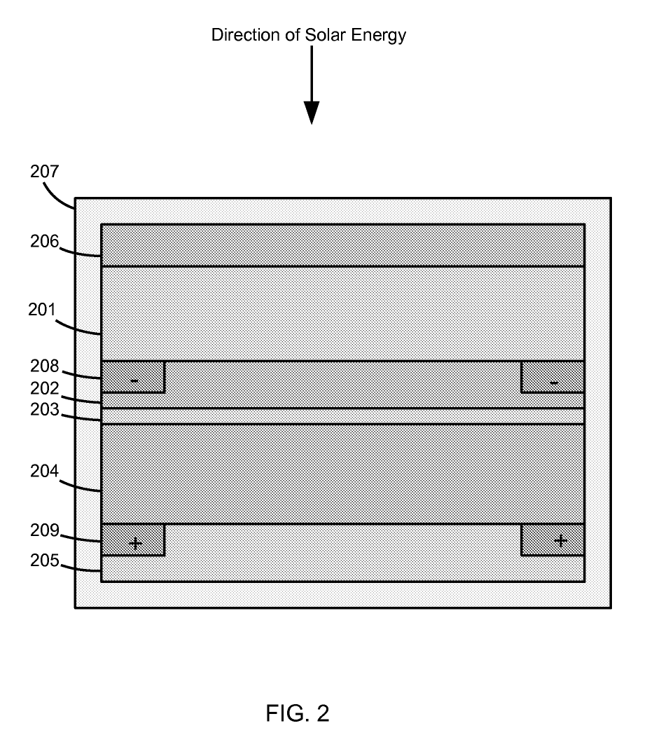

A cross-section view of a second possible embodiment of a polymer solar cell is shown in FIG. 2 and called a superstrate due to the inverted configuration with photonic energy entering the polymer substrate compared to FIG. 1. The first step is to create a polymer substrate 201 using a polycarbonate injection molding machine. Second, a transmissive contact layer 202 is added to the underside with a thickness range of 0.4-2 microns. Anodic (−) bi-layer contact pads 208 made of aluminum, aluminum/nickel, nickel, silver, or the like are deposited on the transmissive contact layer 202. Third, an intrinsic-Zinc Oxide (i-ZnO) n-type highly resistive window layer 203 layer is added to the underside with a thickness of about 0.1 microns. Fourth, a CIGS layer 204 is added to the underside with a thickness of 1.8-2.2 microns. The CIGS layer 204 absorbs photonic energy. Fifth, a highly reflective metal such as gold, silver, or aluminum back contact layer 205 is added to the underside with a thickness of 0.9-1.1 microns. Cathodic (+) contacts 209 are deposited on the back contact layer 205. Sixth, a Magnesium Fluoride (MgF₂) anti-reflective coating 206 is added to the topside of the polymer solar cell. Finally, the entire solar cell is encapsulated 207 using a technique designed to provide environmental protection and give twenty years of service life.

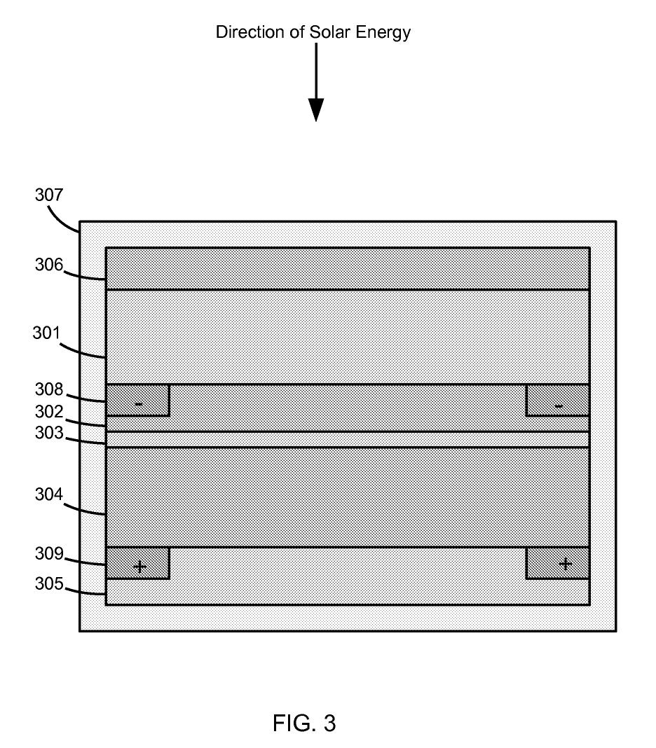

A cross-section view of a third possible embodiment of a polymer solar cell is shown in FIG. 3. The first step is to create a polymer substrate 301 using a polycarbonate injection molding machine. Second, a ZnO or ZnO:Al transmissive conductive layer 302 is added to the underside. Anodic (−) contacts 308 are deposited on the layer 302. Third, a highly resistive intrinsic-ZnO buffer layer 303 is added to the underside. Fourth, a CIGS layer 304 is added to the underside. The CIGS layer 304 absorbs photonic energy. Fifth, a reflective conductive layer 305 is added to the underside. Cathodic (+) contacts 309 are deposited on the reflective conductive layer 305. Sixth, a MgF₂ anti-reflective coating 306 is added to the topside. Finally, the entire solar cell is encapsulated 307 using a technique designed to provide environmental protection and give twenty years of service life.

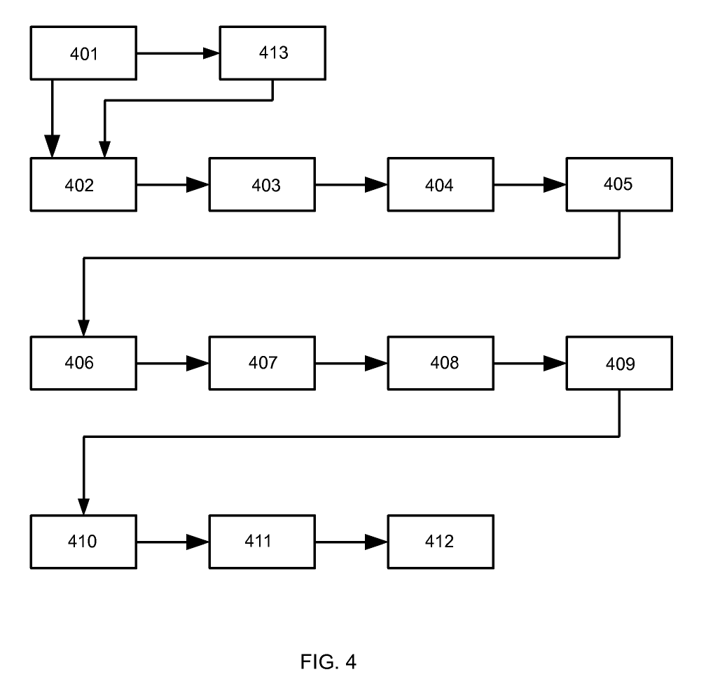

FIG. 4 shows a sequence of steps used to create a polymer solar cell. The sequence of steps comprises: creating a polymer substrate for a solar cell with a polycarbonate injection molding machine 401; storing the substrate in a storage area for subsequent line loading for processing 413; sputtering to deposit a Molybdenum back conductive layer 402 on the substrate, which may come from either step 401 or 413; depositing a p-type CIGS absorber layer 403; using a thermal process chamber for formation of the CIGS absorber layer 404; depositing a ZnMgO or CdS heterojunction partner buffer layer 405; depositing a highly resistive i-ZnO transmissive n-type layer 406; depositing a transmissive conductive oxide layer (doped ZnO:Al) 407; depositing a first bi-layer of Ni, Ag, or the like for a contact pad 408; depositing a second bi-layer of Al, Ag, or the like for a contact pad 409; placing a MgF₂ anti-reflective (AR) coating on the photon entrance side of the solar cell 410; encapsulating the entire solar cell for environmental protection 411; and unload complete substrate from process and storing the completed solar cell substrates in a storage area 412.

Means used to create a polymer substrate for a solar cell with a polycarbonate injection molding machine comprise: a machine with a mold for the desired substrate shape; a galvanic stamper as used in the CD industry with a selected texture for impressing the molded plastic substrate a texture; a molding machine with correct tonnage to mold the solar cell substrates with a polycarbonate resin material and possible borosilicate additive for reduced weight. Conventionally available polycarbonate injection molding machines, or the like, capable of creating a polymer substrate for a solar cell are produced by Krauss-Maffei in Germany or Netstal and Singulus Molding in Switzerland.

Means used to store the substrate in a line storage area comprise: a line substrate loader to feed one substrate at a time to the first semiconductor layer process from a stack of injection molded polycarbonate green (unfinished) substrates. The substrate line loader could be connected direct to the polycarbonate injection molding machine and move the substrate to the first process step or store the substrates until the line is ready to accept the substrates for processing. The substrate storage or loader could be manually loaded with green substrates produced by the injection molding machine at a physically different location.

Means used to deposit a Molybdenum (Mo) conductive layer 1-2 μm thick on the substrate comprise: using DC or RF Magnetron Sputtering with a Mo target in a small vacuum chamber, at argon pressure about 5 microtorr (mT), suited for the shape of the substrate. The sputtering of a thick layer at about 2 μm thickness is for obtaining a dense structure with low resistivity on the order of 12-15 μΩ(cm)⁻², and with good Mo adhesion to the polycarbonate substrate.

Means used to deposit a p-type CIGS absorber layer comprise: depositing the copper indium gallium diselenide metal precursors in bulk on the prior Mo back contact layer in a one or two step sequential process with deposition of the metal layers followed by a selenium incorporation in the metal layers by selenization or sulfurization treatment at high temperature. Deposition by a one step process can be done by using a complete CIGS target or separate sputtering targets. Deposition for a multi step process can use pulsed DC or RF sputtering target in a vacuum chamber. Typical DC magnetron sputtering conditions are to obtain vacuum at a base pressure about 2×10⁻⁷ Torr and a working pressure at 1.0-10 mT with argon gas flow. The CIGS sputtering target(s) consists of a selected CIGS composition with deposition in an argon gas environment.

Means used to use a thermal process chamber for formation of the CIGS absorber layer comprise: rapid thermal processing (RTP) for selenization and/or sulfurization of the metal precursors. The deposited CIGS material layer must be thermally processed to about 550° C. to complete the formation of the absorber layer. Selenium will be deposited in the bulk material layer with the copper, indium, and gallium precursor metals. Because selenium has a much higher vapor pressure than copper, indium, or gallium, an overpressure of an inert gas is required during rapid thermal processing to prevent loss of selenium from the bulk. Semiconductor rapid thermal processing is a high temperature over a very short period of time, or annealing, and includes many known techniques such as; dynamic surface annealing (DSA) to minimize substrate exposure to high temperatures, infrared, flash annealing, tube furnace, laser spike anneal, and/or induction heating, or the like.

Means used to deposit a ZnMgO heterojunction partner buffer layer comprise: deposition of semiconductor material layer by RF magnetron sputtering to about a 30 nm thickness completes the p-n junction of the solar cell, whereas in this disclosure the CIGS absorber layer is of p-type. The buffer layer modifies the CIGS layer surface chemistry and provides beneficial protection during subsequent window layer deposition to complete the solar cell stack. In addition, it is known that ZnMgO as a buffer layer has contributed to obtaining peak conversion efficiencies as discussed in paper by Hariskos et al. 2005, in Thin Solid Films 480-481 (2005) 99-109. ZnMgO also reduces the risk of using the common toxic chemical bath deposition (CBD) of cadmium sulfide (CdS).

Means used to deposit a highly resistive i-ZnO transmissive n-type layer comprise: deposition of the i-ZnO transmissive n-type layer on the ZnMgO buffer layer is done by RF sputtering a 50 nm thick layer in an argon oxygen ambient environment with argon at about 1 mT and oxygen at 0.3 mT.

Means used to deposit a transmissive conductive oxide (TCO) layer (doped ZnO:Al) or AZO comprise: deposition of aluminum (Al) doped ZnO:Al a transmissive conductive contact layer to about 350 nm thick to obtain a very low sheet resistance (Ω/cm²) using RF or DC magnetron sputtering on the prior intrinsic-ZnO window layer. AZO conductive window layer is typically deposited with 2-4% Al metal incorporated in ZnO. Target power density for deposition is ˜3-4 W/cm² with oxygen (O) to argon (Ar) flow rate ˜2:1 and an operating pressure ˜6 mT. AZO has good transmission in the visible region and usable transmission to IR wavelengths as long as ˜2 μm, not reflective and have a cost savings versus a commonly used indium tin oxide (ITO) alternative material per CERAC Inc., a supplier of AZO for solar cells.

Means used to deposit Ni/Al or Ag contact pad/grids comprise: a deposition process by sputtering, evaporation through a mask or recent preferred method using ink jet printing with a fully automated non-contact printing head. Typically used in lab or in industry, the front contacts Ni/Al grids are typically evaporated by e-beam deposition through a mask for a controlled deposition area on the solar cell transmissive conductive oxide layer ZnO:Al. Several commercial sources are now available for ink jet printing the contact/grids on the front conductive window layer of a solar cell.

Means used to place an anti-reflective coating on the photon entrance side of the solar cell comprise: sputter deposition of a 100 nm thick Magnesium fluoride (MgF₂) anti-reflection (AR) coating material, or the like, with a MgF2, or the like, ceramic target. Magnesium fluoride is an ideal AR material due to its good light transparency that includes the ultraviolet (UV) range.

Means used to encapsulate the entire solar cell for environmental protection comprise: using a two-part silicone or ethylene vinyl acetate (EVA) film, or the like, to facilitate encapsulation of the complete solar cell for a lasting service life of 20 plus years. The silicone material can be applied by spincoating or film adhesion process as specified by the manufacturer. EVA is a film that is laminated on the light entrance surface of the solar cell and is not viscid at room temperature, so it can be cut to fit the cell surface prior to lamination system to solidify and have good cell adhesion. The EVA and two-part silicone encapsulants are commercially available as well as the process application equipment.

Means used to store the completed solar cell substrates in a storage area comprise: a process stage to accept complete solar cells from the prior inline station, perform an automated stacking function creating multiple stacks avoiding line stoppage with a continuous line cycle maintained. A full stacking operation would be serviced by operator intervention for inspection audit followed by packaging.

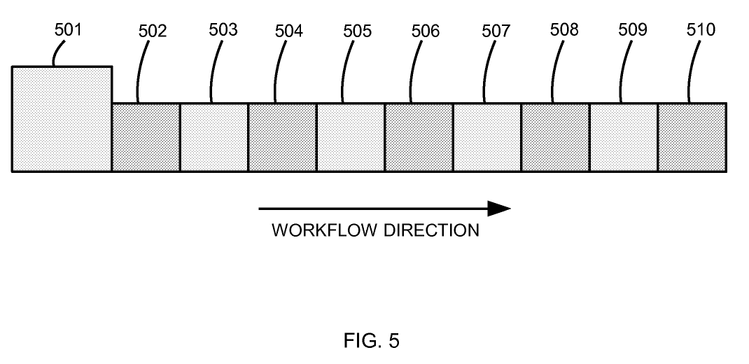

FIG. 5 shows an embodiment of the apparatus used to create a polymer solar cell. Shown in FIG. 5 are: means for creating a polymer substrate for a solar cell with a polycarbonate injection molding machine 501; means for depositing a cathodic contact layer on the polymer substrate 502; means for depositing a photonic energy absorbing layer on the polymer substrate with directed energy 503; means to use a thermal process chamber for formation of a CIGS absorber layer 504; means for depositing a buffer layer on the polymer substrate 505; means for depositing a highly resistive transmissive intrinsic layer with directed energy 506; means for depositing a transmissive contact layer on the polymer substrate 507; means for adding anodic contacts to one of the layers 508; means for depositing an anti-reflective coating layer on the polymer substrate 509; and means for encapsulating the solar cell to provide environmental protection 510.

This apparatus and method will use many techniques that are used to manufacture compact disc media. A blank substrate is molded with a data pit structure on one side of the disc for the laser reader. This apparatus and method will replace the data pits with a texture structure for obtaining more surface area for the CIGS absorption layer. The blank substrate is moved by robotics or other mechanical automation for application of the necessary layers by sputtering or spin coating. The solar cell will require sputtering of the transparent conductor layer, buffer layer, CIGS absorber layer, highly reflective conductive underside, and anti-reflective layer. The encapsulation of the complete cell can be done by a conventional spin coating or protective film layer. Electrical contact points can be added by a conventional method such as sputtering, etching, or printing.

A primary benefit of the invention is the ability to make molded substrates which can employ a Fresnel lens, or the like, feature on the photon entrance side (FIG. 2) of a superstrate solar cell with an inverted configuration. A textured surface can also be molded on the surface of the cell nearest to the CIGS absorber layer, opposite the lens side for a superstrate solar cell, for more surface area to enhance photon absorption. A cell where photonic energy does not pass through the substrate (FIG. 1) would only have the ability for a textured surface on the topside of the polymer substrate.

The Fresnel lens feature allows light to be concentrated or more focused upon entrance, for many equivalent suns energy, onto the CIGS absorber layer. The polymer substrate underside is textured to give the solar cell additional surface area, verses a flat surface, for higher photon absorption capability.

While the disclosure describes embodiments and various alternatives thereto, it should be apparent that the invention is not limited to such embodiments. Rather, many variations would be apparent to persons of skill in the art without departing from the scope and spirit of the invention.

I claim:

1. An apparatus for manufacturing a polymer solar cell, which comprises:
means for creating a polymer substrate for a solar cell with a polycarbonate injection molding machine;
means for depositing a cathodic contact layer on the polymer substrate;
means for depositing a photonic energy absorbing layer on the polymer substrate with directed energy;
means to use a thermal process chamber for formation of a CIGS absorber layer;
means for depositing a buffer layer on the polymer substrate;
means for depositing a highly resistive transmissive intrinsic layer with directed energy;
means for depositing a transmissive contact oxide window layer on the polymer substrate;
means for adding anodic contacts to one of the layers;
means for depositing an anti-reflective coating layer on the polymer substrate; and
means for encapsulating the solar cell to provide environmental protection.

2. The apparatus of claim 1, wherein the polymer substrate contains one or more additives.

3. The apparatus of claim 1, further comprising means for adding a Fresnel lens feature to the polymer solar cell.

4. The apparatus of claim 1, wherein the polymer substrate is textured.

5. The apparatus of claim 2, further comprising means for adding a Fresnel lens feature to the polymer solar cell.

6. The apparatus of claim 2, wherein the polymer substrate is textured.

7. The apparatus of claim 3, wherein the polymer substrate is textured.

8. A method for manufacturing a polymer solar cell, which comprises:
creating a polymer substrate for a solar cell with a polycarbonate injection molding machine;
depositing a cathodic contact layer on the polymer substrate;
depositing a photonic energy absorbing layer on the polymer substrate with directed energy;
using a thermal process chamber for formation of a CIGS absorber layer;
depositing a buffer layer on the polymer substrate;
depositing a highly resistive transmissive intrinsic layer with directed energy;
depositing a transmissive contact layer on the polymer substrate;
adding anodic contacts to one of the layers;
depositing an anti-reflective coating layer on the polymer substrate; and
encapsulating the solar cell to provide environmental protection.

9. The method of claim 8, wherein the polymer substrate contains one or more additives.

10. The method of claim 8, further comprising adding a Fresnel lens feature to the polymer solar cell.

11. The method of claim 8, wherein the polymer substrate is textured.

12. The method of claim 9, further comprising adding a Fresnel lens feature to the polymer solar cell.

13. The method of claim 9, wherein the polymer substrate is textured.

14. The method of claim 10, wherein the polymer substrate is textured.

15. A polymer solar cell prepared in accordance with the method of claim 8.

16. A polymer solar cell prepared in accordance with the method of claim 9.

17. A polymer solar cell prepared in accordance with the method of claim 10.

18. A polymer solar cell prepared in accordance with the method of claim 11.

19. A polymer solar cell prepared in accordance with the method of claim 12.

20. A polymer solar cell prepared in accordance with the method of claim 13.
